(19) United States
(12) Patent Application Publication
(10) Pub. No.: US 2017/0222659 A1
(43) Pub. Date: Aug. 3, 2017

(54) POWER IMPROVEMENT FOR LDPC

(71) Applicant: Silicon Motion Inc., Hsinchu County (TW)

(72) Inventor: Chen-Yu Weng, Kaohsiung City (TW)

(21) Appl. No.: 15/012,872

(22) Filed: Feb. 2, 2016

(51) Int. Cl. H03M 13/11; H03M 13/00

(52) U.S. Cl. CPC H03M 13/1131; H03M 13/1108; H03M 13/1111; H03M 13/616

(57) ABSTRACT

A method for decoding low-density parity check data to decode a codeword is disclosed. The method includes: receiving initial estimates representing a codeword from variable nodes; sending the initial estimates to corresponding check nodes; using all initial estimates to calculate a posteriori probability (APP) values and extrinsic information and sending the APP values and the extrinsic information to the variable nodes; monitoring the extrinsic information (branch information?) received at the check nodes; when the extrinsic information begins to converge, activating a syndrome check for the values at the variable nodes; and when the syndrome check equals zero, activating early termination for the decoding process.

### BACKGROUND OF THE INVENTION

1. Field of the Invention

This invention relates to low-density parity check decoding, and more particularly, to a low-density parity check decoder and decoding method which can save power.

2. Description of the Prior Art

Low-density parity check (LDPC) decoders use a linear error correcting code with parity bits. Parity bits provide a decoder with parity equations which can validate a received codeword. For example, a low-density parity check is a fixed length binary code wherein all the symbols added together will equal zero.

During encoding, all data bits are repeated and transmitted to encoders, wherein each encoder generates a parity symbol. Codewords are formed of k information digits and r check digits. If the length of the codeword is n then the information digits, k, will equal n−r. The codewords can be represented by a parity check matrix, which consists of r rows (representing equations) and n columns (representing digits), and is represented in FIG. 1. The codes are called low-density because the parity matrix will have very few ‘1’s in comparison to the number of ‘0’s. During decoding, each parity check is viewed as a single parity check code, and is then cross-checked with others. Decoding occurs at check nodes, and cross-checking occurs at variable nodes.

LDPC engines support three modes: hard decision hard decoding, soft decision hard decoding, and soft decision soft decoding. FIG. 1 illustrates the parity check matrix H and a Tanner graph, which is another way of representing the codewords, and is used to explain the operation of the LDPC decoder for hard decision soft decoding when using a bit flipping algorithm.

The check nodes, which are represented by the square boxes, are the number of parity bits; and the variable nodes, which are represented by the circular boxes, are the number of bits in a codeword. If a code symbol is involved in a particular equation, a line is drawn between the corresponding check node and variable node. ‘Messages’, which are estimates, are passed along the connecting lines, and combined in different ways at the nodes. Initially, the variable nodes will send an estimate to the check nodes on all connecting lines containing a bit believed to be correct. Each check node then takes all the other connected estimates, makes new estimates for each variable node based on this information, and passes the new estimate back to the variable nodes. The new estimate is based on the fact that the parity check equations force all variable nodes connected to a particular check node to sum to zero.

The variable nodes receive the new information and use a majority rule (a hard decision) to determine if the value of the original bit they sent was correct. If not, the original bit will be ‘flipped’. The bit is then sent back to the check nodes, and these steps are repeated for a predetermined number of iterations or until the parity check equations at the check nodes are satisfied. If these equations are satisfied (i.e. the value calculated by the check nodes matches the value received from the variable nodes) then Early Termination can be activated, which allows the system to exit the decoding process before the maximum number of iterations is reached.

The parity check constraints are performed by doing a syndrome check. A valid codeword will satisfy the equation H. C^{T}=S=0, wherein H is the parity matrix, C is the hard decision codeword and S is the syndrome. When the syndrome equals zero, this means that no further information is required and the decoding process is complete.

Typically, a hard decision and a syndrome check are performed during each iteration, wherein a non-zero syndrome means there is odd parity and a new decoding iteration is required.

As detailed above, syndrome check is usually performed for each iteration in order to activate Early Termination. As it is unlikely that a codeword will pass parity check in the initial iterations, however, performing the syndrome check for each iteration wastes power. If the frequency of the syndrome checks can be reduced, power can be saved.

### SUMMARY OF THE INVENTION

It is therefore an objective of the present invention to provide a system and method for estimating a best time to perform syndrome check, and utilizing this system and method to reduce the frequency of syndrome check operations in an LDPC engine.

A method for decoding low-density parity check data to decode a codeword is disclosed. The method comprises: receiving initial estimates representing a codeword from variable nodes; sending the initial estimates to corresponding check nodes; using all initial estimates to calculate a posteriori probability (APP) values and extrinsic information and sending the APP values and the extrinsic information to the variable nodes; monitoring the extrinsic information (branch information?) received at the check nodes; when the extrinsic information begins to converge, activating a syndrome check for the values at the variable nodes; and when the syndrome check equals zero, activating early termination for the decoding process.

A related low-density parity check (LDPC) decoder for decoding a codeword comprises: a channel memory, for storing channel values; a subtractor, coupled to the channel memory, for subtracting metrics information from the channel values to generate a resultant value for updating the channel values and the metrics information; a processor, coupled to the subtractor, for generating modified metrics information; an adder, coupled to the processor and the channel memory, for combining the modified metrics information and the channel values to generate modified channel values; a low parity detection circuit, coupled to the adder, for detecting the modified channel values; an Early Termination (ET) circuit, coupled to the low parity detection circuit, for performing a syndrome check on the modified channel values and ending the decoding process when the modified channel values pass the syndrome check; and a permutator, coupled between the low parity detection circuit and the ET circuit, wherein when the low parity detection circuit determines that the modified channel values converge to a same sign, the permutator will send the modified channel values to the ET circuit, and when the LP detection circuit determines that the modified channel values do not converge to a same sign, the permutator will begin another iteration of the LDPC decoder without sending the modified channel values to the ET circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration of a parity check matrix Tanner graph for low-density parity check decoding.

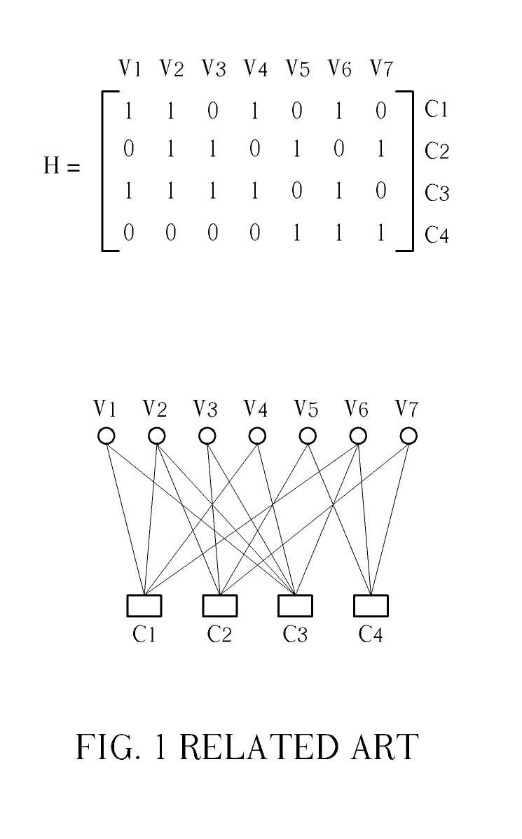

FIG. 2 is a diagram of an LDPC decoder according to an exemplary embodiment of the present invention.

### DETAILED DESCRIPTION

An objective of the present invention is to determine a best time for activating the syndrome check in order to save power. The aim is to only perform the syndrome check at a time when the result is likely to equal zero, rather than performing the syndrome check each iteration as in the prior art.

Two equations are used to illustrate the method of the present invention. As detailed in the ‘Background’ section, when the syndrome is equal to zero, this means the parity check is satisfied and the decoding can be exited. The syndrome is determined by multiplying the variable node values with the parity check matrix, as detailed in equation 1.

H.C^{T}=S (1)

When S=zero, this indicates that the decoder can be terminated and the hard decision output. Otherwise, the decoding will continue for a next iteration.

The present invention also uses a sum-product decoding algorithm, rather than the bit flipping algorithm, as a means to determine when syndrome check can be activated. In the sum-product algorithm, the messages representing each decision are probabilistic values. In the bit flipping algorithm, although hard decisions are made, what is actually received is real values wherein the sign (0 or 1) represents a positive or negative decision, respectively, and the magnitude of the value represents a level of confidence in the decision. This is known as soft information. Sum-product algorithms can use this soft information by computing an a posteriori probability value APPⱼ for each bit, which is the probability that a certain bit will equal 1 if all the parity checks are met. An approximation of the APPⱼ is computed over a series of iterations.

The iterations follows those of the bit flipping algorithm, except that each time what is calculated is the probability that a parity check equation will be satisfied if the bit is a particular value. Each time the check node returns a probability value, it will also return extrinsic information which is independent of the probability value for that bit which is then used by the variable node as a priori information for the next iteration.

The relation between the variable node values, the check node values, and the a posteriori probability values for sum-product decoding are represented by equation 2.

APPⱼ−Rᵢⱼ=Qᵢⱼ (2)

where APPⱼ is the a posteriori probability sent by the check node, Qᵢⱼ is the response from the variable node and Rᵢⱼ is the extrinsic information from the check node. Subscript j represents a parity check equation and subscript i represents a bit of the code.

In the sum-product algorithm, when a codeword is found, APPⱼ will gradually converge. From equation (2), it can be seen that as APPⱼ gradually converges into a codeword, Rᵢⱼ will also converge but will be smaller than APPⱼ. Further, the sign of Qᵢⱼ will be approximately equal to the sign of APPⱼ as it converges. Therefore, by implementing a detection circuit which determines when the check node values converge to a same sign, the LDPC system can determine at what time the syndrome check should be activated.

When the syndrome check is then activated, the Qᵢⱼ value is put into equation (1) to determine if the parity check constraints are satisfied. Once the codeword meets the parity check, Early Termination can be activated and the decoding process can end without having to go through a maximum number of iterations.

By turning off the syndrome check until it is determined that extrinsic (soft) information sent from the check node converges to a same sign, power wasted on performing syndrome check for each iteration, even when the codeword is unlikely to meet parity constraints, can be saved. A simple detection circuit can detect the sign of the extrinsic information, which does not require complicated circuitry to be added to the LDPC engine.

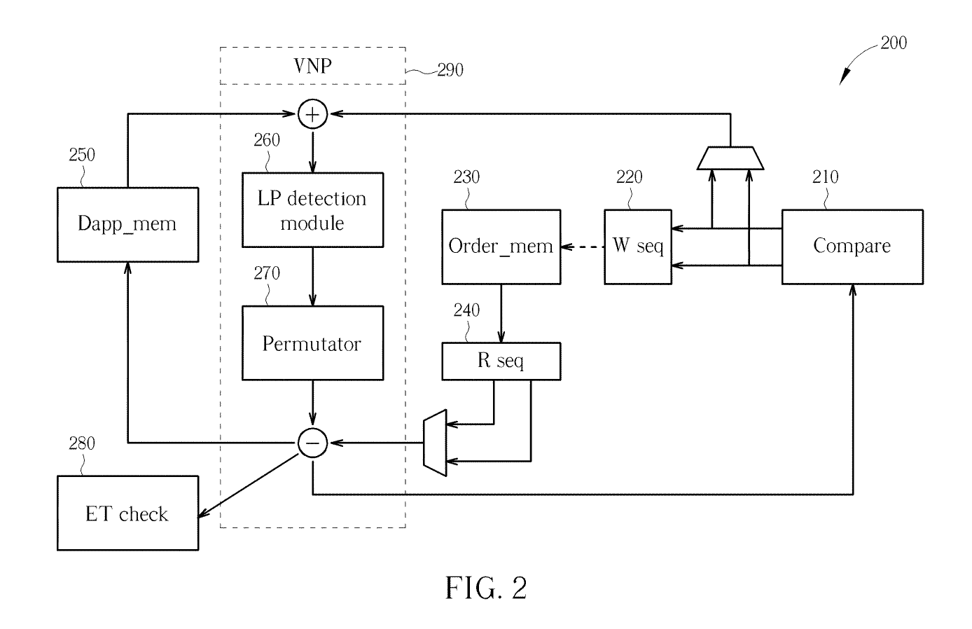

Please refer to FIG. 2, which illustrates an LDPC decoding engine 200 according to an exemplary embodiment of the present invention. The order memory 230 receives log likelihood rations (LLR) corresponding to received symbols and stores them in the form of vectors, which will form channel values. The channel values and corresponding metrics are passed to a subtractor, and D values are sent to the compare circuit 210 for updating the channel values. The D values are also sent to the Dapp memory 250, and are sent to a processer block 290, which outputs modified metrics. The modified channel values and metrics are combined at the adder to generate a new APP value. In the prior art, this new APP value would be directly sent to the permutator 270, which would then activate a syndrome check via the Early Termination (ET) Check circuit 280. As illustrated in FIG. 2, however, the LDPC decoding engine 200 also comprises a low parity (LP) detection module 260, which examines the Rᵢⱼ values received from the adder to determine when they converge to the same sign and therefore to determine whether the Qᵢⱼ value is stable. If this condition is met, the permutator 270 will pass the data to the ET Check circuit 280. If the condition is not satisfied, the permutator 270 will directly start a new iteration without activating a syndrome check.

The present invention therefore can save power when using a sum-product algorithm for hard decision soft decoding of low-density parity check codes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for decoding low-density parity check data to decode a codeword, the method comprising:
receiving initial estimates representing a codeword from variable nodes;
sending the initial estimates to corresponding check nodes;
using all initial estimates to calculate a posteriori probability (APP) values and extrinsic information and sending the APP values and the extrinsic information to the variable nodes;
monitoring the extrinsic information received at the check nodes;
when the extrinsic information begins to converge to a same sign, activating a syndrome check for the initial estimates; and
when the syndrome check equals zero, activating early termination for the decoding process.

2. The method of claim 1, wherein when the extrinsic information does not begin to converge, the method further comprises:
updating the initial estimates using the received APP values and extrinsic information;
sending the updated estimates to the corresponding check nodes; and
using all initial estimates to calculate a posteriori probability (APP) values and extrinsic information and sending the APP values and the extrinsic information to the variable nodes.

3. The method of claim 2, wherein the method steps are repeated for a predetermined number of iterations.

4. The method of claim 1, wherein the decoding process uses a sum-product algorithm.

5. A low-density parity check (LDPC) decoder for decoding a codeword, comprising:
a channel memory, for storing initial estimates;
a subtractor, coupled to the channel memory, for generating a resultant value for updating the initial estimates;
a processor, coupled to the subtractor, for generating a posteriori probability (APP) values and extrinsic information;
an adder, coupled to the processor and the channel memory, for combining the a posteriori probability (APP) values and the initial estimates to generate updated initial estimates;
a low parity detection circuit, coupled to the adder, for detecting the updated initial estimates;
an Early Termination (ET) circuit, coupled to the low parity detection circuit, for performing a syndrome check on the updated initial estimates and ending the decoding process when the updated initial estimates pass the syndrome check; and
a permutator, coupled between the low parity detection circuit and the ET circuit, wherein when the low parity detection circuit determines that the extrinsic information converges to a same sign, the permutator will send the updated initial estimates to the ET circuit.

6. The LDPC decoder of claim 5, wherein when the LP detection circuit determines that the extrinsic information does not converge to a same sign, the permutator will begin another iteration of the LDPC decoder without sending the updated initial estimates to the ET circuit.

7. The LDPC decoder of claim 6, wherein the method steps are repeated for a predetermined number of iterations.

8. The LDPC decoder of claim 5, wherein the decoding process uses a sum-product algorithm.
